(19) United States
(12) Patent Application Publication
(10) Pub. No.: US 2026/0255514 A1
(43) Pub. Date: Aug. 27, 2026

(54) FIELD DEVICE HOUSING ASSEMBLY WITH TRANSPARENT PANEL

(71) Applicant: Rosemount Inc., Shakopee, MN (US)

(72) Inventors: Samuel Joseph Onsrud, Eden Prairie, MN (US); Jacob D. Holm, Savage, MN (US)

(21) Appl. No.: 19/063,951

(22) Filed: Feb. 26, 2025

(51) Int. Cl. H05K 5/03; H05K 5/00; H05K 5/06

(52) U.S. Cl. CPC H05K 5/03; H05K 5/0018; H05K 5/061

(57) ABSTRACT

A field device housing assembly includes a main housing and a cover having a proximal end connected to the main housing, the cover includes an interior wall, a flange extending radially inward from the interior wall toward the central axis and a locking lip located on the interior wall between the flange and the proximal end. A transparent panel is received within a socket defined by the interior wall and the flange of the cover. A spring-loaded retainer ring is secured to the interior wall wherein the transparent panel is clamped between a distal face of the retainer ring and the flange. The spring-loaded retainer ring secures the transparent panel and has a spring-loaded fin which extends in a proximal direction from the retainer ring face.

### BACKGROUND

Embodiments of the present disclosure relate to industrial process field device housing assemblies and, more specifically, to field device housing assemblies having a transparent panel.

Industrial process field devices, such as process transmitters, are used in industrial process control and monitoring systems to monitor industrial process variables using process sensors (e.g., pressure sensor, temperature sensor, etc.) and/or control one or more control devices (e.g., actuators, valves, etc.) that interact with an industrial process.

Many industrial process facilities are located in corrosive environments, or may be subject to a risk of fire, explosion, or vibration. As a result, industrial field devices must generally be constructed to be explosion-proof and otherwise able to withstand operating environment conditions. For example, a field device generally includes a housing assembly containing circuitry of the transmitter that is configured to meet applicable flameproof and explosion-proof standards, such as those imposed by the International Electrotechnical Commission (IEC) (e.g., requiring ATEX and IECx flameproof/explosion-proof certifications), Canadian Standards Association (CSA) and FM Global.

Some field devices are equipped with a user interface that allows a technician to configure the field device without having to access the interior of the housing assembly. The user interface may include a display, which is viewable through a transparent panel, or window, formed of plastic or glass in a cover of the housing assembly, and buttons that may be used to access menu items and enter settings.

The window formed in the cover presents a challenge to meet flameproof and explosion- proof requirements for the housing assembly. Conventional techniques typically utilize a potted joint around the circumference of the window that is filled with potting. Such a potted joint is problematic for many reasons including minimum joint lengths, significant manufacturing scrap, added complexity in the housing assembly, added overhead to potting control, qualification and testing, constraints related to sourcing, and temperature limitations of the potting. Additionally, because the potted joint does not allow for re-work, misalignment between the window and the cover may require the parts to be scrapped. Furthermore, voids may occur in the potting material, adhesion issues, or curing issues, all of which can go undetected, can result in product failures.

Alternatives to the potted joint generally require extremely tight tolerancing to meet minimum gap spacing requirements in applicable approval standards. Such tight tolerancing results in high part costs. One example design which addresses these issues is shown and described in US Patent 11,513,018, entitled FIELD DEVICE HOUSING ASSEMBLY and issued on November 29, 2022. However, there is an ongoing need for improvements in such configurations.

### SUMMARY

A field device housing assembly includes a main housing and a cover having a proximal end connected to the main housing, The cover includes an interior wall, a flange extending radially inward from the interior wall toward the central axis and a locking lip located on the interior wall between the flange and the proximal end. A transparent panel is received within a socket defined by the interior wall and the flange of the cover. A spring-loaded retainer ring is secured to the interior wall wherein the transparent panel is clamped between a distal face of the retainer ring and the flange. The spring-loaded retainer ring has a spring-loaded fin which extends in a proximal direction from the retainer ring distal face and is urged in a radially outward direction such that a proximal end of the spring-loaded fin engages with the locking lip of the cover and the retainer ring distal face abuts the transparent panel and urges the transparent panel against the flange. The transparent panel is flush with the interior wall of the cover and the retainer ring distal face. In one specific aspect, the transparent panel forms two ninety degree angles with an adjacent component.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 is a simplified diagram of an exemplary industrial process measurement system, in accordance with embodiments of the present disclosure.

FIG. 2 is a simplified diagram of an example of a field device in accordance with embodiments of the present disclosure.

FIG. 3 is a simplified front view of an example of a field device housing assembly, in accordance with embodiments of the present disclosure.

FIG. 4 is a simplified side cross-sectional view of a portion of a field device housing assembly, in accordance with the prior art.

FIG. 5A is a top perspective of and FIG. 5B is a side plan view of a spring loaded retaining ring in accordance with one example embodiment of the present invention.

FIGS. 6A and 6B are side cross-sectional views of a cover and the spring loaded retaining ring. In FIG. 6A the retaining ring is fully inserted into the cover to lock a transparent panel in place. In FIG. 6B the retaining ring is partially inserted in the cover.

FIG. 7 is a side cross-sectional view of the portion of an assembly in accordance with the present invention illustrating force lines due the retaining ring locked into the cover.

FIG. 8 is a side cross-sectional view of a portion of the assembly of the invention showing a flame path.

FIG. 9A is a side cross-sectional perspective view of a cover and FIG. 9B is a plan view of a spring loaded retaining ring in accordance with another example embodiment.

### DETAILED DESCRIPTION OF ILLUSTRATIVE EMBODIMENTS

Embodiments of the present disclosure are described more fully hereinafter with reference to the accompanying drawings. Elements that are identified using the same or similar reference characters refer to the same or similar elements. The various embodiments of the present disclosure may be embodied in many different forms and should not be construed as limited to the specific embodiments set forth herein. Rather, these embodiments are provided so that this disclosure will be thorough and complete, and will fully convey the scope of the present disclosure to those skilled in the art.

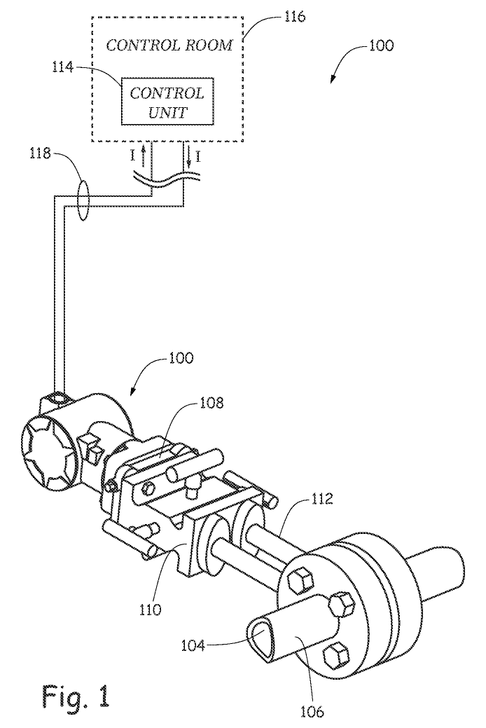

FIG. 1 is a simplified diagram of an exemplary industrial process measurement and/or control system 100, in accordance with embodiments of the present disclosure. The system 100 may be used in the processing of a material to transform the material from a less valuable state into more valuable and useful products, such as petroleum, chemicals, paper, food, etc. For example, the system 100 may be used in an oil refinery that performs industrial processes that can process crude oil into gasoline, fuel oil, and other petrochemicals.

The system 100 includes a field device 102, such as a process transmitter (e.g., a pressure transmitter), that is used to measure and/or control a process, such as a process medium 104. In some embodiments, the process medium 104 may be a fluid (i.e., liquid or gas) that is contained or transported through a process vessel 106, such as a pipe (shown), a tank, or another process vessel. The field device 102 may be coupled to the vessel 106 through an adapter 108, a manifold 110 and a process interface 112, for example.

The field device 102 may communicate with a computerized control unit 114, which may be remotely located from the field device 102, such as in a control room 116, as shown in FIG. 1. The control unit 114 may be communicatively coupled to the field device 102 over a suitable physical communication link, such as a two-wire control loop 118, or a wireless communication link. Communications between the control unit 114 and the field device 102 may be performed over the control loop 118 in accordance with conventional analog and/or digital communication protocols. In some embodiments, the control loop 118 includes a 4-20 milliamp control loop, in which a process variable or other value may be represented by a level of a loop current I flowing through the control loop 118. Exemplary digital communication protocols include the modulation of digital signals onto the analog current level of the two-wire control loop 118, such as in accordance with the HART@ communication standard. Other purely digital techniques may also be employed, including FieldBus and Profibus communication protocols.

The field device 102 may also be configured to communicate wirelessly with the control unit 114 using a conventional wireless communication protocol. For example, the field device 102 may be configured to implement a wireless mesh network protocol, such as WirelessHART® (IEC 62591) or ISA 100.1la (IEC 62734), or another wireless communication protocol, such as WiFi, LoRa, Sigfox, BLE, or any other suitable protocol.

Power may be supplied to the field device 102 from any suitable power source. For example, the field device 102 may be wholly powered by the current I flowing through the control loop 118. One or more power supplies may also be utilized to power the field device 102, such as an internal or an external battery. An electrical power generator (e.g., solar panel, a wind power generator, etc.) may also be used to power the field device 102, or to charge a power supply used by the field device 102.

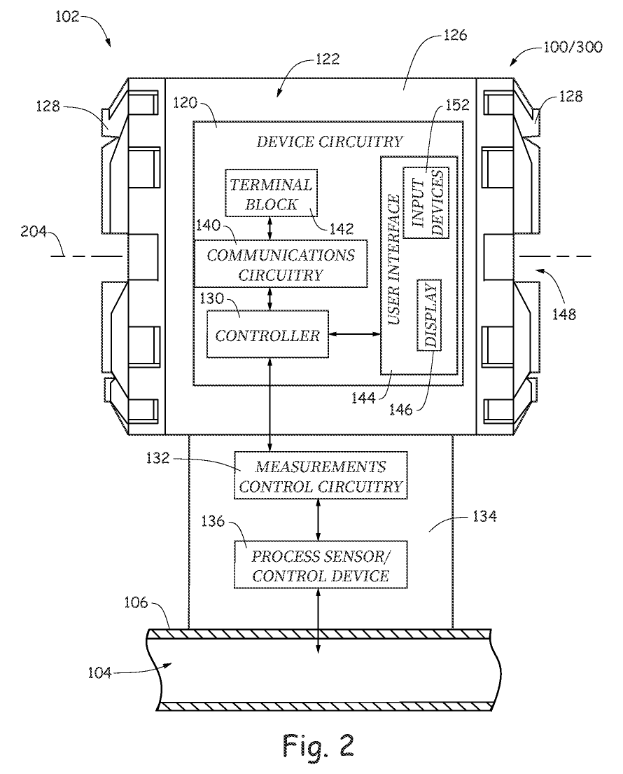

FIG. 2 is a simplified diagram of an example of a field device 102, in accordance with embodiments of the present disclosure. In some embodiments, the field device 102 includes device circuitry 120 contained within an interior cavity 122 of a housing assembly 124. The housing assembly 124 includes a main housing 126 and one or more covers 128 that operate to seal the interior cavity 122. In some embodiments, the housing assembly 124 is designed to meet applicable flameproof and explosion-proof standards for field devices without the use of potting, such as those imposed by the IEC (e.g., IEC 60079-1:2014 § 5.2.9), the CSA (e.g., CSA C22.2 No. 30 R2016), and FM Global (e.g., FM3615:2018), for example.

Embodiments of the device circuitry 120 include a controller 130 configured to communicate with measurement or control circuitry 132, which may be contained within a separate module 134 to which the housing assembly 124 is connected. The controller 130 may communicate with the circuitry 132 using conventional techniques (e.g., feed through wires, etc.) while maintaining the flameproof and explosion proof properties of the housing assembly 124.

The controller 130 may represent one or more processors (i.e., microprocessor, central processing unit, etc.) that control components of the field device 102 to perform one or more functions described herein in response to the execution of instructions, which may be stored locally in patent subject matter eligible computer readable media or memory of the device 102. In some embodiments, the processors of the controller 130 are components of one or more computer-based systems. In some embodiments, the controller 130 includes one or more control circuits, microprocessor-based engine control systems, one or more programmable hardware components, such as a field programmable gate array (FPGA), for example. The controller 130 may also represent other conventional field device circuitry.

The measurement or control circuitry 132 represents circuitry that interacts with an active component 136 in the form of a process sensor and/or control device. Process sensor forms of the active component 136 may be used to sense or measure a parameter of the process 104, such as a temperature, a level, a pressure, a flow rate, or another parameter of the process 104 using one or more sensors represented by the active component 136. Exemplary process sensors 136 include pressure sensors, temperature sensors, level sensors, flow rate sensors, pH sensors, and/or other sensors used to sense or measure a process parameter. For example, the field device 102 shown in FIG. 1 is a pressure transmitter having one or more pressure sensors. The measurement or control circuitry 132 may translate an output from a process sensor 136 (e.g., process parameter value) and communicate the translated output to the controller 130.

Control device forms of the active component 136 generally represent devices that are configured to interact with an aspect of the process 104. Exemplary control devices 136 include actuators, solenoids, valves, and other conventional process control devices used in field devices to control a process involving the process material 104. The measurement or control circuitry 132 may control the control device 136 based on signals from the controller 130.

The device circuitry 120 may also include communications circuitry 140 that is generally configured to communicate with an external device, such as the control unit 114 (FIG. 1) using a suitable communication protocol, such as one of those mentioned above. For example, the communications circuitry 140 may receive signals from the controller 130, such as a process parameter value, and communicate the value to the control unit 114. Similarly, the communications circuitry 140 may receive control signals that are used by the controller 130 to control the control device 136. In some embodiments, the communications circuitry 140 utilizes a terminal block 142, which may be connected to the two-wire process control loop 118 (FIG. 1), to facilitate communications between the field device and the control unit.

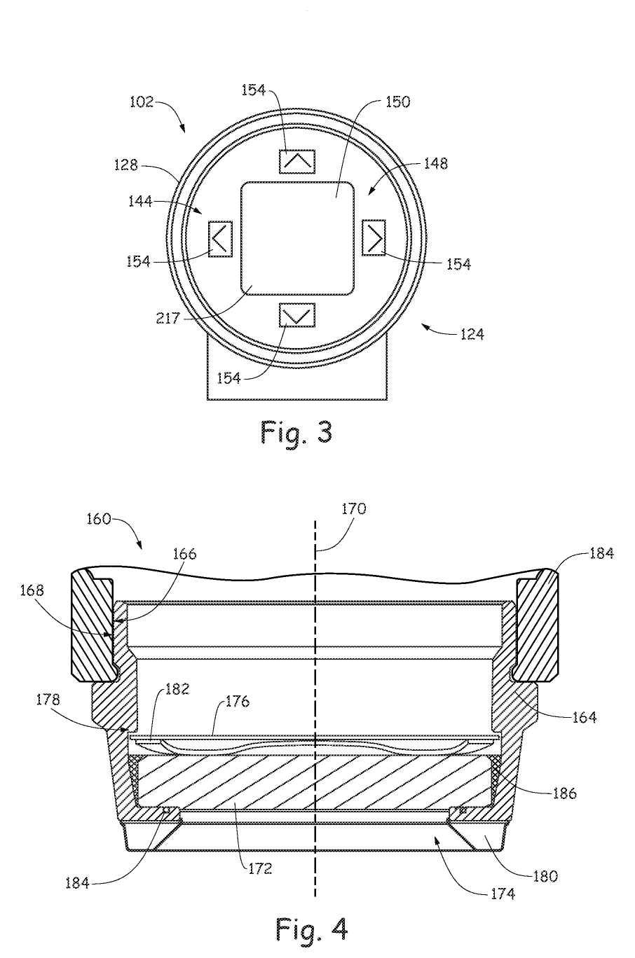

In some embodiments, the device circuitry 120 includes circuitry for providing a user interface 144 comprising a display 146. The display 146 may include one or more liquid crystal displays (LCDs) with optional backlighting functionality, or as any other type of digital or analog display capable of producing a visual output. In some embodiments, the display 146 is viewable through a window 148 formed by a transparent panel (e.g., glass or plastic) in the cover 128 of the housing assembly 124, as shown in FIG. 3, which is a simplified front view of an example of the field device housing assembly 124, in accordance with embodiments of the present disclosure.

The user interface 144 may also include one or more input devices 152 to enable touch actuation input to the user interface 144 by an operator. In one embodiment, the input devices 152 may include one or more buttons 154 (e.g., capacitive buttons), examples of which are shown in FIG. 3. The buttons 154 may be configured as desired for particular applications. In some embodiments, the input devices 152 and the display 146 are located adjacent to one another, as shown in FIG. 3. For example, the buttons 154 may be formed on the cover 128 next to the window 148.

As mentioned above, conventional techniques for meeting flameproof and explosion-proof standards for industrial process field devices have utilized a potted joint around the circumference of the transparent panel. An example of such a technique is shown in FIG. 4, which is a simplified side cross-sectional view of a portion of a field device housing assembly 160, in accordance with the prior art. The housing assembly 160 includes a main housing 162 and a cover 164, which operates to seal an interior cavity 166 of the main housing 162 to protect circuitry of the field device while meeting certain flameproof and explosion-proof standards.

The cover 164 may connect to the main housing 162 through a suitable threaded attachment formed by the threaded engagement between a threaded section 166 of the main housing 162 and a threaded section 168 of the cover 164, which are concentric to a central axis 170. The cover 164 includes a transparent panel 172 that forms a window 174 for viewing a display within the housing 160 through an opening in the end of the cover. A metal snap ring 176 is positioned beneath a shoulder 178, and the panel 172 is pressed against a flange 180 by a metal wave spring 182 that is compressed between the metal snap ring 176 and the panel 172. An O-ring 184 may be positioned within an annular groove of the flange to seal the junction between the panel 172 and the flange 180.

In order to meet flameproof and explosion-proof standards, a potted joint 186 is formed between the transparent panel 172 and the cover 164. The potted joint 186 is generally formed using urethane potting (e.g., parts A and B). Such a potted joint 186 is problematic for many reasons including minimum joint lengths, significant manufacturing scrap, added complexity in the housing assembly, added overhead to potting control, qualification and testing, constraints related to sourcing, and temperature limitations of the potting. Furthermore, alternatives to the potted joint 186 generally require extremely tight tolerancing to meet minimum gap spacing requirements in applicable approval standards. Such tight tolerancing drives high part costs. Additionally, because the potted joint does not allow for re-work, misalignment between the window and the cover or other issue may require the parts to be scrapped. Furthermore, voids may occur in the potting material, adhesion issues, or curing issues, all of which can go undetected, can result in product failures.

Embodiments of the present disclosure are generally directed to field device housing assemblies that provide alternatives to the use of potting to seal and meet flameproof and explosion-proof standards, such as the potted joint 186 of the prior art housing assembly 160 shown in FIG. 4, while avoiding issues with use of potting, such as those mentioned above including tight tolerancing and the inability to rework components, for example. Additional embodiments are directed to field devices 102 that include the field device housing assemblies 124 (FIG. 2). Another technique that does not require potting material is shown in US Patent 11,513,018, entitled FIELD DEVICE HOUSING ASSEMBLY and issued on November 29, 2022. However, this technique requires threading on an interior wall and retainer ring which may be inconsistent due to cross threading and galling. Further, the manufacturing process for such a configuration may be difficult to automate.

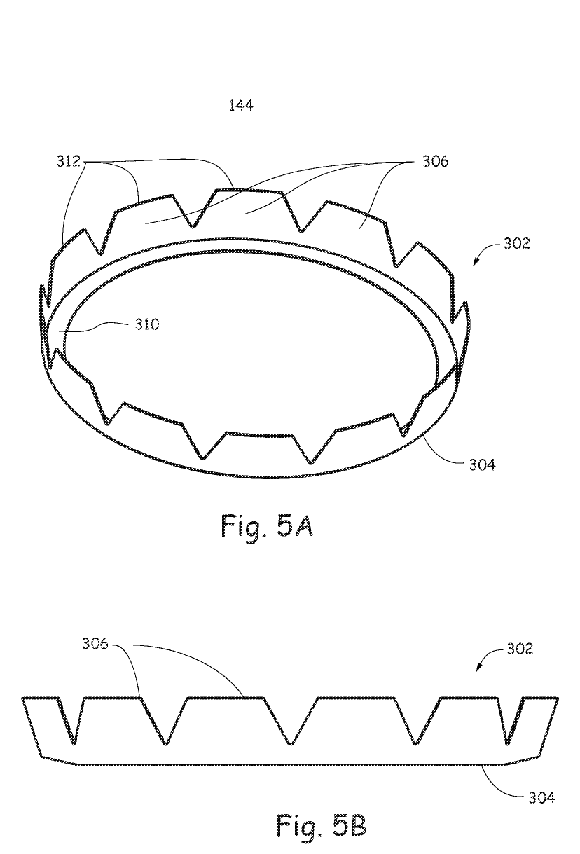

With the present invention, a spring loaded retaining ring is used to secure a transparent panel to a cover of a field device. FIG. 5A is a perspective view and FIG. 5B is a side plan view of a spring loaded retaining ring 302 in accordance with one example embodiment. Spring loaded retaining ring 302 includes a distal face 304 and a plurality of spring loaded fins 306. In one configuration, the spring loaded fins 306 have a trapezoid shape. The spring loaded springs 306 extend in a proximal direction away from distal face 304. An optional spring loaded interior ring face 310 can also be provided along distal face 304. Each of the plurality of spring loaded fins 306 include proximal face 312.

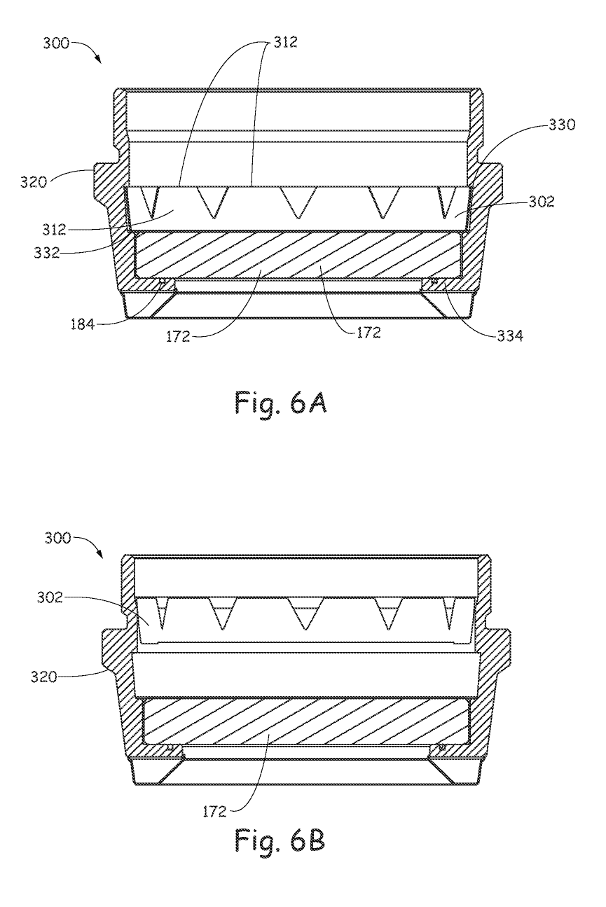

FIG. 6A is a side cross-sectional view of housing assembly 300 including spring loaded retaining ring 302 locked into a cover 320 which is adapted to be received by housing 126 shown in FIG. 2. The spring loaded retaining ring 302 is used to mount transparent panel 172 in cover 320 as discussed herein. FIG. 6B is a side cross-sectional view of assembly 300 in which spring loaded retaining ring 302 is partially inserted into cover 320. The cover 320 includes a proximal locking lip 330 and a distal ring flange 332 along with a panel flange 334. A circular O-ring 184 preferably extends around flange 334. The proximal face 312 of each of the spring loaded retaining fins 306 is urged in a radial direction and locked into locking lip 330. The spring loaded ring 310 of distal face 304 of spring loaded retaining ring 302 is pressed against transparent panel 172 along its outer circumference. This urges the transparent panel 172 against flange 334 and O-ring 184.

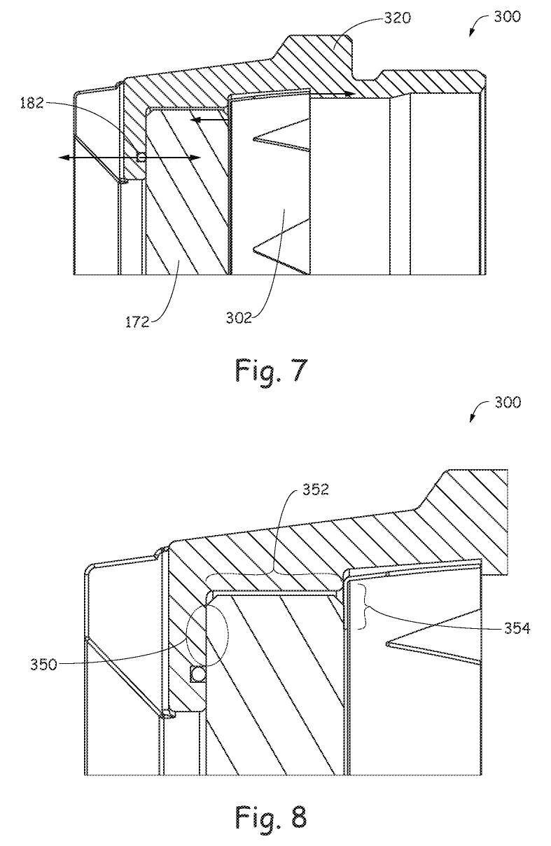

FIG. 7 shows the axial directed force lines which are used to urge the transparent panel 172 against O-ring 182. As illustrated in FIG. 7, which is a cross-sectional view of a portion of the assembly 300, a force against locking lip 330 is transferred through the spring loaded retaining ring 302 to a proximal side of transparent panel 172. This presses the distal side of panel 172 against O-ring 182 and thereby seals the panel 172 against the flange 334. In one example configuration, the spring loaded fins 306 return to their original shape after the retaining ring 302 has been inserted between locking lip 330 and distal ring flange 332.

FIG. 8 is a cross-sectional view similar to FIG. 7 of a portion of assembly 300. FIG. 8 illustrates three distinct flame paths 350, 352 and 354 each defined by 90 degree changes in the direction of the flame path. This arrangement creates a spigot/flange and a multistep flame path which meets hazardous location flame path requirements. The spigot plus flange joint is illustrated at the circle at 350. This distance must be a minimum length to comply with the applicable hazardous location standard. The remaining steps in the multistep path are illustrated at 352 and 354. A multistep flame path requires at least three adjacent segments where the flame path changes direction no less two times by an amount of 90 degrees.

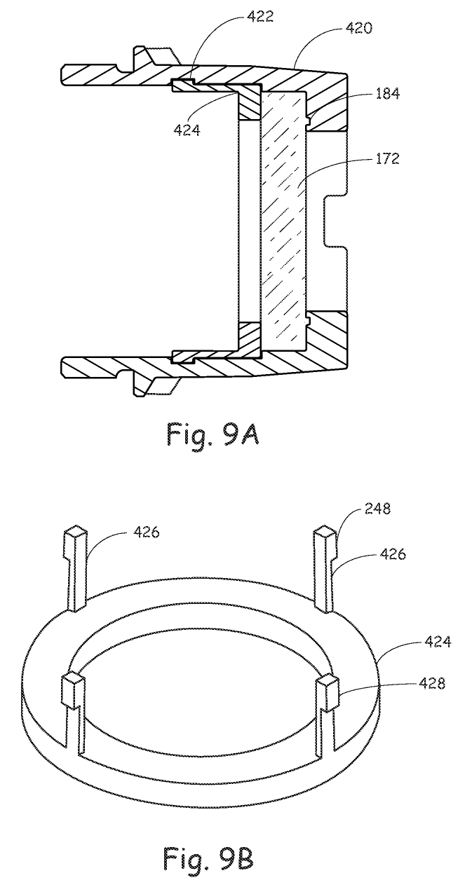

FIGS. 9A and 9B illustrate another example embodiment of the invention. In this configuration, a cover 420 includes an interior notch 422 which forms the locking lip. A spring loaded retaining ring 424 includes fins 426 in the form of elongate armatures which extend in a proximal direction. At the proximal end of the armatures 426 are pegs 428 which lock into the notches 422. This again causes the retaining ring 424 to press against transparent panel 172 providing a seal with O-ring 184.

With this configuration, the assembly time of the assembly 300 is greatly reduced and easily automated. The components can be sequentially inserted into the cover 320 by an automated assembly process. Further, the spring loaded configuration reduces the necessary tolerance requirements and further does not require precise threading.

Each of the housing assemblies 124 is configured to meet applicable flameproof and explosion-proof standards for field devices 102 without the use of potting, such as those imposed by the IEC (e.g., IEC 60079-1:2014 § 5.2.9), the CSA (e.g., CSA C22.2 No. 30 R2016), and FM Global (e.g., FM3615:2018), for example. Thus, in some embodiments, the housing assemblies 124 and the field devices 102 utilizing the housing assemblies 124 do not include potting or a potted joint. Instead, the housing assemblies 124 meet such flameproof and explosion-proof requirements through the formation of a multi-step joint and a spigot plus flange joint at the junction of the transparent panel 150 and the cover 128. The multi-step joint classification applies for ATEX and IECEx flameproof/explosion-proof approvals per the IEC standard, and the spigot plus flange joint applies to FM Global and CSA standards. In some embodiments, the spigot plus flange joint has a non-compliant gap, which removes the need for tight tolerances. In some embodiments, the multi-step joint/spigot plus flange joint results in a flame path that turns a minimum of two times and by not less than ninety degrees (+/-5 degrees).

A field device 102 may use the housing assembly 300 in place of the housing assembly 124, such that the device circuitry 120 is contained within the interior cavity of the housing assembly 300. The device circuitry 120 may be configured to communicate a process parameter value to an external location based on a received process sensor output, and/or control a process control device, as discussed above.

As discussed herein, embodiments of the housing assembly do not utilize a potted joint or potting to satisfy flameproof and explosion-proof requirements. Rather, a multi-step flame path is provided. Although the embodiments of the present disclosure have been described with reference to preferred embodiments, workers skilled in the art will recognize that changes may be made in form and detail without departing from the spirit and scope of the present disclosure.

What is claimed is:

1. A field device housing assembly comprising:
a main housing;
a cover having a proximal end connected to the main housing, an interior wall, a flange extending radially inward from the interior wall toward the central axis and a locking lip located on the interior wall between the flange and the proximal end;
a transparent panel received within a socket defined by the interior wall and the flange; and
a spring loaded retainer ring secured to the interior wall, wherein the transparent panel is clamped between a distal face of the retainer ring and the flange, the spring loaded retainer ring having a spring loaded fin which is urged in a radially outward direction such that the spring loaded fin engages with the locking lip of the cover and the retainer ring distal face abuts the transparent panel and urges the transparent panel against the flange;
wherein the transparent panel is flush with the interior wall of the cover and the retainer ring distal face.

2. The assembly of claim 1 wherein a first edge of the transparent panel contacts the interior wall along a ninety-degree angle.

3. The assembly of claim 1 wherein a second edge of the transparent panel contacts the spring loaded retainer ring along a ninety-degree angle.

4. The assembly of claim 1 wherein the assembly does not include a potted joint between the transparent panel and the cover.

5. The assembly of claim 2 wherein a multi-step joint and a spigot plus flange joint is formed between the transparent panel, the interior wall of the cover and the spring loaded retainer ring.

6. The assembly of claim 1 wherein:
the spring loaded retainer ring distal face is a spring loaded distal face which abuts a proximal face of the transparent panel; and
the transparent panel is clamped between the spring loaded distal face of the spring loaded retainer ring and the flange of the cover.

7. The assembly of claim 6 wherein a threaded portion of the cover of the spring loaded retainer ring extends between the cover and the transparent panel, wherein a plane that is perpendicular to the central axis extends through the transparent panel and the cover.

8. The assembly of claim 7 wherein an interior side of the transparent panel is clamped against the flange of the cover.

9. The assembly of claim 6 wherein:
a proximal side of the transparent panel is exposed to an interior of the cover and is clamped against the flange portion of the spring loaded retainer ring; and
an exterior side of the transparent panel is clamped against the flange of the cover.

10. The assembly of claim 1 wherein the spring loaded retainer ring is a stamped spring loaded retainer ring.

11. The assembly of claim 1 wherein the spring loaded fin is a trapezoid.

12. The assembly of claim 11 wherein the trapezoid extends in a proximal direction.

13. The assembly of claim 1 including a plurality of spring loaded fins.

14. The assembly of claim 1 wherein the spring loaded fin is an armature.

15. The assembly of claim 14 wherein the armature extends in a proximal direction.

16. The assembly of claim 1 wherein the locking lip comprises a notch in the interior wall of the cover.

17. The assembly of claim 1 wherein the cover, transparent panel and spring loaded retaining ring create one flame path comprising three segments with two ninety degree angles.

18. The assembly of claim 1 including an O-ring between the transparent panel and the flange of the cover.
